(19) United States
(12) Patent Application Publication
(10) Pub. No.: US 2026/0059883 A1
(43) Pub. Date: Feb. 26, 2026

(54) SINGLE-PHOTON AVALANCHE DIODE AND IMAGE SENSING DEVICE INCLUDING THE SAME

(71) Applicant: SK hynix Inc., Icheon-si (KR)

(72) Inventor: Sun Ho OH, Icheon-si (KR)

(21) Appl. No.: 19/306,931

(22) Filed: Aug. 21, 2025

(30) Foreign Application Priority Data
Aug. 26, 2024 (KR) 10-2024-0114382

(51) Int. Cl. H10F 39/00; H10F 30/225; H10F 39/18

(52) U.S. Cl. CPC H10F 39/807; H10F 30/225; H10F 39/18; H10F 39/811

(57) ABSTRACT

An image sensing device includes single-photon avalanche diodes (SPADs) disposed adjacent to each other; and a connection region located between two adjacent SPADs among the SPADs. Each of the SPADs includes: an output node configured to output a voltage pulse; and a biasing node disposed to overlap the output node and configured to receive a bias voltage, wherein the connection region connects the biasing nodes included in the SPADs.

### CROSS-REFERENCE TO RELATED APPLICATION

This application claims the benefit of priority to Korean Patent Application No. 10-2024-0114382, filed in the Korean Intellectual Property Office on Aug. 26, 2024, the entire contents of which are incorporated herein by reference.

### TECHNICAL FIELD

The present disclosure relates to a single-photon avalanche diode and an image sensing device including the same.

### BACKGROUND

Time of Flight (TOF) technology may extract a distance by emitting light in the form of a pulse from a light source disposed within or near a sensor, receiving light reflected from a detection target, and measuring the time therebetween.

For precise TOF measurement, detection has to be performed immediately after reflected light reaches a light receiving element, and therefore a photoelectric conversion element with very high sensitivity is required.

A single-photon avalanche diode (SPAD) is an optical element capable of being manufactured using CMOS technology. The single-photon avalanche diode has very high gain characteristics and has high photoelectric conversion efficiency sufficient to detect a single photon.

The single-photon avalanche diode may amplify and recognize an emitted photon using the avalanche multiplication effect, thereby enabling precise TOF measurement.

### SUMMARY

The present disclosure has been made to solve the above-mentioned problems occurring in the prior art while advantages achieved by the prior art are maintained intact.

An aspect of the present disclosure provides an image sensing device for adjusting photon detection efficiency and/or resolution.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, an image sensing device includes single-photon avalanche diodes (SPADs) disposed adjacent to each other; and a connection region located between two adjacent SPADs among the SPADs. Each of the SPADs includes: an output node configured to output a voltage pulse; and a biasing node disposed to overlap the output node and configured to receive a bias voltage, wherein the connection region connects the biasing nodes included in the SPADs.

According to an embodiment, the output node may be a cathode, and the biasing node may be an anode.

According to an embodiment, the output node may be an anode, and the biasing node may be a cathode.

According to an embodiment, the image sensing device may further include a first separation structure located between the two adjacent SPADs and a second separation structure disposed external to the SPADs.

According to an embodiment, the first separation structure may overlap the connection region.

According to an embodiment, the second separation structure may include a protruding structure that extends toward the first separation structure, and the connection region may be located between the first separation structure and the protruding structure.

According to an embodiment, the biasing node may have a circular shape.

According to an embodiment, the biasing node may have a rounded rectangular shape.

According to an embodiment, an impurity doping type of the output node may be different from an impurity doping type of the biasing node.

According to an embodiment, the first separation structure and the second separation structure may be included in a substrate, and a depth of the first separation structure that extends from a first surface of the toward a second surface of the substrate opposite to the first surface of the substrate may be smaller than a depth of the second separation structure.

According to an embodiment, the first separation structure and the second separation structure are included in a substrate and a depth of the first separation structure that extends from a first surface of the substrate toward a second substrate of the substrate opposite to the first surface of the substrate may be equal to a depth of the second separation structure.

According to an embodiment, the bias voltage may be either a first bias voltage outputting a voltage pulse from each of the SPADs or a second bias voltage outputting a voltage pulse from only a SPAD to which the bias voltage is provided.

According to another aspect of the present disclosure, an image sensing device includes a substrate having a first surface on which light is incident; single-photon avalanche diodes (SPADs) located inside the substrate to be adjacent to each other; a connection region configured to connect two adjacent ones of the SPADs; a first separation structure located between the two adjacent ones of the SPADs; and a second separation structure located external to the SPADs, wherein the first separation structure extends toward the connection region from the first surface of the substrate.

According to an embodiment, each of the SPADs may include an output node in contact with a second surface of the substrate that is opposite to the first surface of the substrate and a biasing node that overlaps the output node and that is located inside the substrate.

According to an embodiment, a doping type of the output node may be different from a doping type of the biasing node.

According to an embodiment, the second separation structure may extend from the first surface of the substrate to a second surface of the substrate that is opposite to the first surface of the substrate.

According to an embodiment, the connection region may have a smaller width than the SPADs.

According to an embodiment, the connection region may have a smaller thickness than the SPADs.

### BRIEF DESCRIPTION OF THE DRAWINGS

The above and other objects, features and advantages of the present disclosure will be more apparent from the following detailed description taken in conjunction with the accompanying drawings:

FIG. 1 is a block diagram illustrating an imaging device according to an embodiment of the present disclosure.

FIG. 2 is a view illustrating an embodiment of a unit pixel included in a pixel array illustrated in FIG. 1.

FIG. 3 is a view illustrating an embodiment of a unit pixel included in the pixel array illustrated in FIG. 1.

FIG. 4 is a view illustrating an embodiment of a unit pixel included in the pixel array illustrated in FIG. 1.

FIG. 5 is a view illustrating an embodiment of a cross-sectional structure taken along a first cutting line of FIG. 2.

FIG. 6 is a view illustrating an embodiment of a cross-sectional structure taken along the first cutting line of FIG. 2.

FIG. 7 is a view illustrating an embodiment of a unit pixel included in the pixel array illustrated in FIG. 1.

FIG. 8 is a view illustrating an embodiment of a cross-sectional structure taken along a second cutting line of FIG. 7.

FIG. 9 is a view illustrating an embodiment of a cross-sectional structure taken along a third cutting line of FIG. 7.

FIG. 10 is a view illustrating an embodiment of a unit pixel included in the pixel array illustrated in FIG. 1.

FIG. 11 is a view illustrating an embodiment of a cross-sectional structure taken along a fourth cutting line of FIG. 10.

FIG. 12 is a view illustrating an embodiment of a cross-sectional structure taken along a fifth cutting line of FIG. 10.

### DETAILED DESCRIPTION

Hereinafter, various embodiments of the present disclosure will be described with reference to accompanying drawings. Accordingly, those of ordinary skill in the art will recognize that modification, equivalent, and/or alternative on the various embodiments described herein can be made based on what is described or illustrated in this document.

The drawings are not necessarily to scale, and in some instances, the proportions of at least some of the structures illustrated in the drawings may be exaggerated to clearly depict features of the embodiments. When a multi-layer structure having two or more layers is disclosed in the drawings or the detailed description, the relative positional relationship or arrangement order of the layers as illustrated only reflects a specific embodiment, and the present disclosure is not limited thereto. The relative positional relationship or arrangement order of the layers may vary. In addition, the drawing or detailed description of the multi-layer structure may not reflect all of the layers existing in the specific multi-layer structure (e.g., one or more additional layers may exist between two layers illustrated). For example, when a first layer is “on” or “over” a second layer or a substrate in the multi-layer structure in the drawing or detailed description, this may mean not only that the first layer is directly formed on the second layer or the substrate, but also that one or more other layers exist between the first layer and the second layer or between the first layer and the substrate.

Hereinafter, a single-photon avalanche diode and an image sensing device including the same according to embodiments of the present disclosure will be described in detail with reference to the accompanying drawings.

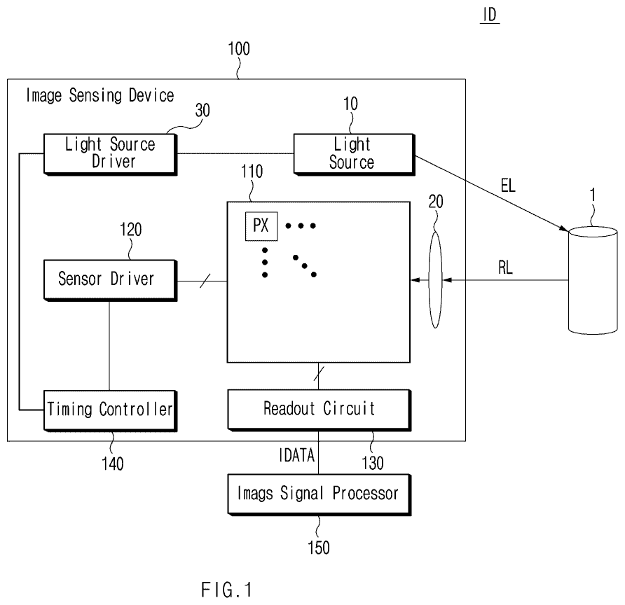

FIG. 1 is a block diagram illustrating an imaging device according to an embodiment of the present disclosure.

Referring to FIG. 1, the imaging device ID may refer to a device such as a digital still camera that takes a still image or a digital video camera that takes a moving image. For example, the imaging device ID may be implemented as a digital single lens reflex (DSLR) camera, a mirrorless camera, or a smart phone, but is not limited thereto. The imaging device ID may be a concept including a device that includes an imaging element and is capable of photographing a subject and generating an image. According to an embodiment, the imaging device ID may be a Lidar sensor.

The imaging device ID may include an image sensing device 100 and an image signal processor (ISP) 150.

The image sensing device 100 may be a complementary metal oxide semiconductor image sensor (CIS) that converts incident light into an electrical signal. The image sensing device 100 may include a light source 10, a lens module 20, a light source driver 30, a pixel array 110, a sensor driver 120, a readout circuit 130, and a timing controller 140.

The light source 10 may emit light to a target object 1 under the control of the light source driver 30. The light source 10 may be a laser diode (LD) that emits light in a specific wavelength band (e.g., near-infrared light, infrared light, or visible light), a light emitting diode (LED), a near-infrared laser (NIR), a point light source, a monochromatic light source in which a white lamp and a monochromator are combined, or a combination of other laser light sources. For example, the light in the specific wavelength band may be light in an infrared wavelength band that has a wavelength of 800 nm to 1000 nm (hereinafter, referred to as the “infrared light”), and in the present disclosure, it is assumed that the light source 10 emits the infrared light. Meanwhile, the light emitted from the light source 10 may be pulse light having a period, an amplitude, and a pulse width determined in advance. For convenience of description, only one light source 10 is illustrated in FIG. 1, but a plurality of light sources may be arranged around the lens module 20.

The lens module 20 may collect light reflected from the target object 1 and may focus the collected light on pixels PX of the pixel array 110. For example, the lens module 20 may include a focusing lens having a glass or plastic surface or other cylindrical optical elements. The lens module 20 may include a plurality of lenses aligned with respect to an optical axis.

The light source driver 30 may drive the light source 10 under the control of the timing controller 140. In particular, the light source driver 30 may control the waveform (period, amplitude, and pulse width) of emitted light EL output from the light source 10.

The pixel array 110 may include the plurality of pixels PX continuously arranged in a two-dimensional matrix structure (e.g., continuously arranged in a column direction and/or a row direction). Under the control of the sensor driver 120, each of the plurality of pixels PX may detect incident light incident through the lens module 20 and may generate a pixel signal.

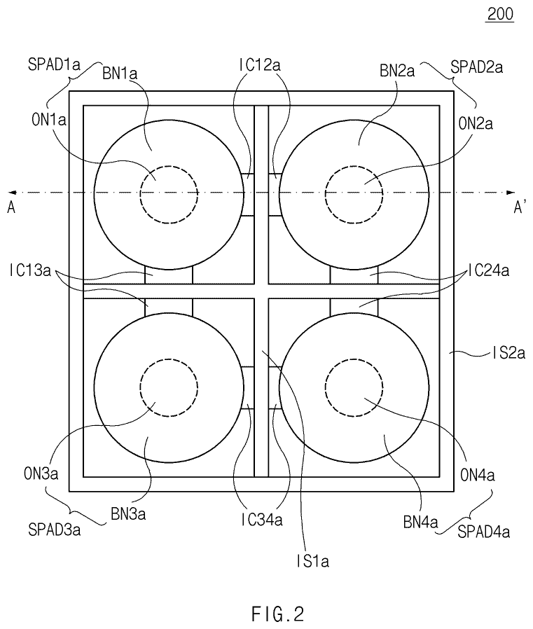

Each pixel PX may be an infrared pixel that generates a pixel signal by detecting incident light including arriving light RL that is incident on the pixel by reflection of the emitted light EL, which is emitted from the light source 10, from the target object 1. In this disclosure, it is assumed that the arriving light RL is incident on the pixel PX by the reflection of the emitted light EL from the target object 1. However, the spirit and scope of the present disclosure is not limited thereto. For example, the light source 10 may be provided in a separate device other than the image sensing device 100, and the emitted light EL emitted from the light source 10 may be directly incident on the pixel array 110. In the present disclosure, the infrared pixel may be a depth pixel for calculating the distance to the target object 1, and according to an embodiment, the infrared pixel may include a pixel for generating an infrared image by simply detecting infrared light incident from a scene, rather than arriving light. According to an embodiment, the pixels PX may include a pixel for generating a color image by detecting visible light incident from a scene. Hereinafter, it is assumed that each pixel PX is a single-photon avalanche diode (SPAD) pixel for detecting the distance to the target object 1 according to a direct ToF method. The more detailed structure and operation of each unit pixel PX will be described below with reference to FIG. 2 and the following drawings.

The sensor driver 120 may drive the pixels PX of the pixel array 110 in response to a timing signal output from the timing controller 140. For example, the sensor driver 120 may generate a control signal to select and control pixels PX included in at least one row line among a plurality of row lines of the pixel array 110.

The readout circuit 130 may process a pixel signal output from the pixel array 110 under the control of the timing controller 140 to generate and store depth data for detecting the distance to the target object 1. Specifically, the readout circuit 130 may calculate candidate time of flight corresponding to a SPAD pulse that each pixel generates by detecting incident light including arriving light and may store the candidate time of flight corresponding to the SPAD pulse in units of sub-frames. The readout circuit 130 may transmit the candidate time of flight stored in units of sub-frames to the image signal processor 150 under the control of the timing controller 140. In the present disclosure, for convenience of description, the candidate time of flight may be used interchangeably with the time of flight.

The timing controller 140 may generate a timing signal to control operation of the light source driver 30, the sensor driver 120, and the readout circuit 130. According to an embodiment, the timing controller 140 may generate the timing signal based on a pre-stored sequence, data transferred from the readout circuit 130, and/or a request of the image signal processor 150. According to an embodiment, the timing controller 140 may include a logic control circuit, a phase lock loop (PLL) circuit, a timing control circuit, and a communication interface circuit.

The image signal processor 150 may perform image signal processing on image data IDATA received from the image sensing device 100 to generate processed image data. The image signal processor 150 may reduce noise for the image data IDATA and may perform image signal processing for improving image quality, such as interpolation of the image data IDATA and lens distortion correction.

The image data IDATA may include the above-described candidate time of flight stored in units of sub-frames. The image signal processor 150 may accumulate data in units of sub-frames to generate a histogram for one frame and may determine target time of flight for one frame based on the histogram. The target time of flight may be determined for each pixel PX, and the image signal processor 150 may calculate a target distance that is the distance to the target object 1 that is detected by each pixel PX, based on the target time of flight of the pixel PX. A set of target distances for the pixels PX included in the pixel array 110 may be referred to as a depth image and may be included in the processed image data.

The image signal processor 150 may transmit the processed image data to a host device (not illustrated). The host device (not illustrated) may be a processor (e.g., an application processor) that processes the processed image data received from the image signal processor 150, a memory (e.g., a non-volatile memory) that stores image data, or a display device (e.g., a liquid crystal display (LCD)) that visually outputs image data.

In addition, the image signal processor 150 may transmit a control signal for controlling operation of the image sensing device 100 (whether to operate, operation timing, and an operation mode) to the image sensing device 100.

FIG. 2 is a view illustrating an embodiment of a unit pixel 200 included in the pixel array illustrated in FIG. 1.

FIG. 2 illustrates a plan view of the unit pixel 200, taken from the direction of the incident light on the pixel array.

Referring to FIG. 2, the unit pixel 200 included in the pixel array may include a first SPAD SPAD1a, a second SPAD SPAD2a, a third SPAD SPAD3a, and a fourth SPAD SPAD4a that are arranged in a 2×2 matrix including two rows and two columns.

The first to fourth SPADs (SPAD1a, SPAD2a, SPAD3a, and SPAD4a) may be continuously arranged in the row direction ROW or the column direction COLUMN of the pixel array.

Each of the SPADs may include a biasing node that receives a bias voltage and an output node that outputs a voltage pulse.

The first SPAD SPAD1a may include a first biasing node BN1a and a first output node ON1a. The second SPAD SPAD2a may include a second biasing node BN2a and a second output node ON2a. The third SPAD SPAD3a may include a third biasing node BN3a and a third output node ON3a. The fourth SPAD SPAD4a may include a fourth biasing node BN4a and a fourth output node ON4a.

In the example as shown in FIG. 2, the SPADs, SPAD1a, SPAD2a, SPAD3a, and SPAD4a, may include the biasing nodes (BN1a, BN2a, BN3a, and BN4a), each having a circular shape, and the output nodes (ON1a, ON2a, ON3a, and ON4a), each having a circular shape.

Each of the first to fourth SPADs (SPAD1a, SPAD2a, SPAD3a, and SPAD4a) may receive the bias voltage.

The bias voltage may be a voltage capable of operating each of the first to fourth SPADs (SPAD1a, SPAD2a, SPAD3a, and SPAD4a) in a Geiger mode.

The Geiger mode may refer to an operation mode in which a reverse bias voltage, where a voltage between a cathode and an anode is higher than a breakdown voltage, is applied to a photosensitive photodiode SPAD including a P-N junction.

In the Geiger mode, avalanche breakdown may be triggered by a single photon incident on the SPAD, and a voltage pulse may be output.

A node to which the reverse bias voltage for the Geiger mode operation is provided may be referred to as a biasing node, and a node from which the voltage pulse is output may be referred to as an output node.

For example, the first SPAD SPAD1a may include the first biasing node BN1a and the first output node ON1a. In the example, the shapes of the biasing nodes and the output nodes included in the SPADs (SPAD1a, SPAD2a, SPAD3a and SPAD4a) may be substantially the same. Therefore, the first SPAD SPAD1a will be described below as the representative example, and such description may be applied to the remaining SPADs, SPAD2a, SPAD3a and SPAD4a while omitting the repetitive description.

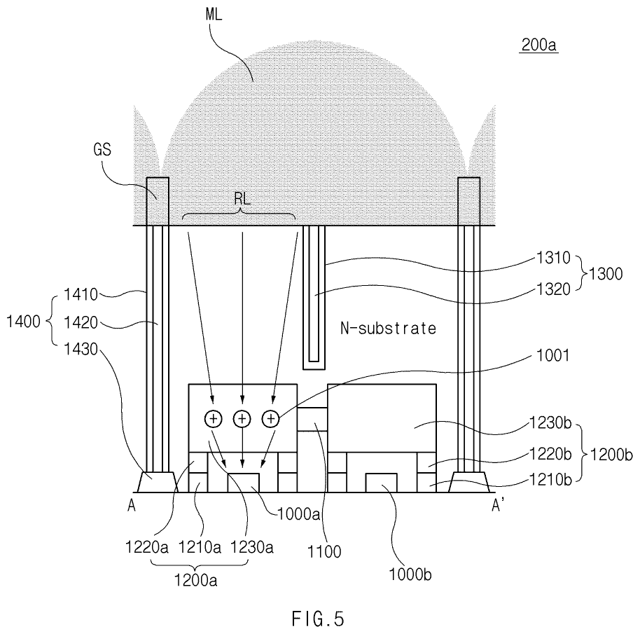

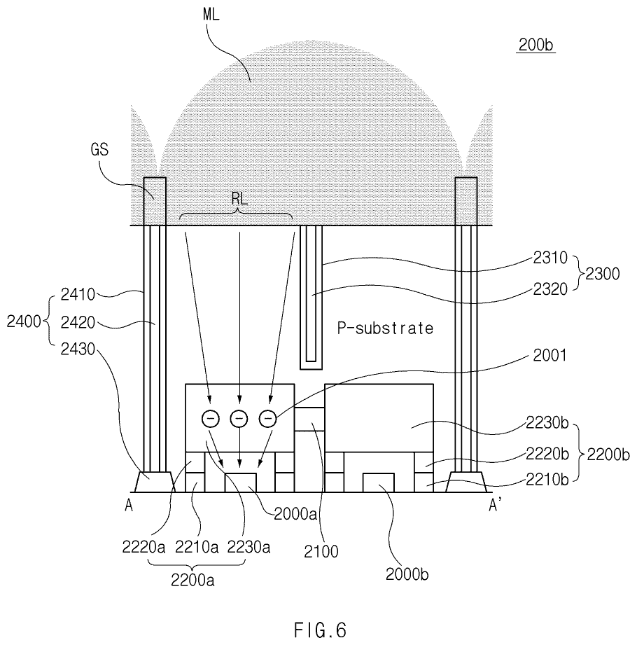

The first biasing node BN1a may overlap the first output node ON1a. The first output node ON1a may be disposed at the center of the first SPAD SPAD1a and may have a circular shape. The first biasing node BN1a may be spaced apart from the first output node ON1a by a certain distance and may have a shape that surrounds the first output node ON1a while being disposed external to the first output node ON1a. The specific shapes of the first output node ON1a and the first biasing node BN1a will be described in detail with reference to FIGS. 5 and 6.

An edge breakdown phenomenon or a tunneling phenomenon in which charges are directly transferred from a biasing node to an output node may be prevented because the first biasing node BN1a and the first output node ON1a are spaced apart from each other by the certain distance.

The bias voltage may be individually applied to each of the first to fourth SPADs SPAD1a, SPAD2a, SPAD3a, and SPAD4a.

The first biasing node BN1a and the first output node ON1a may be doped with different impurity types from each other.

For example, the first biasing node BN1a may be doped with an N-type impurity, and the first output node ON1a may be doped with a P-type impurity. In this case, a semiconductor substrate including the first biasing node BN1a and the first output node ON1a may be a semiconductor substrate doped with an N-type impurity.

The first biasing node BN1a doped with the N-type impurity may be or operate as a cathode of the first SPAD SPAD1a. In addition, the first output node ON1a doped with the P-type impurity may be or operate as an anode of the first SPAD SPAD1a. Accordingly, the first SPAD SPAD1a including the first biasing node BN1a doped with the N-type impurity may be referred to as a cathode biasing SPAD.

According to an embodiment, the first biasing node BN1a may be doped with a P-type impurity, and the first output node ON1a may be doped with an N-type impurity. In this case, the semiconductor substrate including the first biasing node BN1a and the first output node ON1a may be or include a semiconductor substrate doped with a P-type impurity.

The first biasing node BN1a doped with the P-type impurity may be or operate as an anode of the first SPAD SPAD1a. In addition, the first output node ON1a doped with the N-type impurity may be or operate as a cathode of the first SPAD SPAD1a. Accordingly, the first SPAD SPAD1a including the first biasing node BN1a doped with the P-type impurity may be referred to as an anode biasing SPAD.

A connection region may be disposed between two SPADs that are adjacent to each other in the row direction ROW or the column direction COLUMN of the 2×2 matrix.

The unit pixel 200 may include a first connection region IC12a that connects the first biasing node BN1a and the second biasing node BN2a, a second connection region IC13a that connects the first biasing node BN1a and the third biasing node BN3a, a third connection region IC24a that connects the second biasing node BN2a and the fourth biasing node BN4a, and a fourth connection region IC34a that connects the third biasing node BN3a and the fourth biasing node BN4a.

The connection regions are formed in a repetitive shape in the unit pixel 200. Therefore, for convenience of description, the first connection region IC12a disposed between the first SPAD SPAD1a and the second SPAD SPAD2a will be described, and repetitive description will be omitted.

The first connection region IC12a may be disposed between the first SPAD SPAD1a and the second SPAD SPAD2a. More specifically, the first connection region IC12a may electrically connect the first biasing node BN1a and the second biasing node BN2a.

The first connection region IC12a may be a region doped with the same impurity type as the first biasing node BN1a and the second biasing node BN2a.

As the connection regions (IC12a, IC13a, IC24a, and IC34a) are formed, the plurality of SPADs (SPAD1a, SPAD2a, SPAD3a, and SPAD4a) may operate as one SPAD or may operate as individual SPADs.

In some implementations, depending on the magnitude of the bias voltage provided to one of the SPADs (SPAD1a, SPAD2a, SPAD3a, and SPAD4a) included in the unit pixel 200, the plurality of SPADs (SPAD1a, SPAD2a, SPAD3a, and SPAD4a) connected by the connection regions (IC12a, IC13a, IC24a, and IC34a) may operate as one SPAD or may individually operate.

As described above, the bias voltage may be a voltage capable of operating each of the first to fourth SPADs (SPAD1a, SPAD2a, SPAD3a, and SPAD4a) in the Geiger mode. In the example, the bias voltage may be a voltage randomly selected from voltages which satisfies a condition that the voltage between the cathode and the anode of the photosensitive photodiode SPAD is higher than the breakdown voltage.

In the image sensing device according to an embodiment of the present disclosure, the first to fourth biasing nodes (BN1a, BN2a, BN3a, and BN4a) are electrically connected by the connection regions (IC12a, IC13a, IC24a, and IC34a). Depending on the magnitude of the voltage applied to the first biasing node BN1a, a certain voltage higher than the noise range may be generated in the remaining SPADs (SPAD2a, SPAD3a, and SPAD4a) or not. For example, when a high voltage higher than or equal to a preset voltage is applied to the first biasing node BN1a, an additional voltage pulse beyond a noise range may be generated in the second to fourth SPADs (SPAD2a, SPAD3a, and SPAD4a).

In contrast, when a low voltage lower than the preset voltage is applied to the first biasing node BN1a, a voltage pulse may be generated only in the first SPAD SPAD1a, and a voltage pulse beyond the noise range may not be generated in the second to fourth SPADs (SPAD2a, SPAD3a, and SPAD4a).

The preset voltage for determining whether a voltage pulse beyond the noise range is generated in other SPADs (e.g., the second to fourth SPADs, SPAD2a, SPAD3a, and SPAD4a) connected with the first SPAD (SPAD1a) to which a bias current is applied may vary depending on various factors including at least one of the shapes of the connection regions (IC12a, IC13a, IC24a, and IC34a), the distances between the biasing nodes (BN1a, BN2a, BN3a, and BN4a), the doping concentrations of the connection regions (IC12a, IC13a, IC24a, and IC34a), or the doping concentrations of the biasing nodes (BN1a, BN2a, BN3a, and BN4a).

For example, as the connection areas of the connection regions (IC12a, IC13a, IC24a, and IC34a) and the biasing nodes (BN1a, BN2a, BN3a, and BN4a) and the doping concentration are increased, the preset voltage may be decreased.

When a high voltage higher than or equal to the preset voltage is applied to the first SPAD (SPAD1a) included in the unit pixel 200, a photon may be detected in all of the first to fourth SPADs (SPAD1a, SPAD2a, SPAD3a, and SPAD4a) included in the unit pixel 200, and a voltage pulse corresponding to the detected photon may be output.

When a high voltage higher than or equal to the preset voltage is applied to any biasing node (e.g., the first biasing node BN1a) included in the unit pixel 200, all of the SPADs (SPAD1a, SPAD2a, SPAD3a, and SPAD4a) included in the unit pixel 200 may operate in the Geiger mode, and thus photon detection efficiency (PDE) may be increased.

An operation mode in which a high voltage higher than or equal to the preset voltage is applied to any biasing node (e.g., the first biasing node BN1a) included in the unit pixel 200 so that the photon detection efficiency is increased may be referred to as a first mode.

When a low voltage lower than the preset voltage is applied to the first SPAD (SPAD1a) included in the unit pixel 200, a photon may be detected only in the first SPAD SPAD1a, and a voltage pulse corresponding to the detected photon may be output.

In the example, when a low voltage lower than the preset voltage is applied to any biasing node (e.g., the first biasing node BN1a) included in the unit pixel 200, only the SPAD (e.g., SPAD1a) to which the low voltage is applied may operate in the Geiger mode.

Thus, when a low bias voltage lower than the preset voltage is provided to a selected SPAD (e.g., SPAD1a) among the plurality of SPADs (SPAD1a, SPAD2a, SPAD3a, and SPAD4a) included in the unit pixel 200, only the selected SPAD may be allowed to operate in the Geiger mode.

A voltage pulse may be output from a SPAD operating in the Geiger mode among the plurality of SPADs (SPAD1a, SPAD2a, SPAD3a, and SPAD4a) included in the unit pixel 200. Thus, by selecting the SPAD to which the bias voltage is applied and adjusting the magnitude of the bias voltage applied to the selected SPAD, four different voltage pulses may be obtained from the plurality of SPADs (SPAD1a, SPAD2a, SPAD3a, and SPAD4a) included in one unit pixel 200.

When four SPADs (SPAD1a, SPAD2a, SPAD3a, and SPAD4a) included in one unit pixel 200 individually operate, four different signals may be output from the one unit pixel 200, and the resolution of the image sensing device may be increased.

An operation mode in which a low voltage lower than the preset voltage is applied to any biasing node (e.g., the first biasing node BN1a) included in the unit pixel 200 so that the SPADs (SPAD1a, SPAD2a, SPAD3a, and SPAD4a) individually operate and the resolution is increased may be referred to as a second mode.

The unit pixel 200 may include a first separation structure IS1a located between the four SPADs (SPAD1a, SPAD2a, SPAD3a, and SPAD4a) and a second separation structure IS2a surrounding the four SPADs (SPAD1a, SPAD2a, SPAD3a, and SPAD4a). In the example, the second separation structure IS2a is located external to the four SPADs (SPAD1a, SPAD2a, SPAD3a, and SPAD4a). In the example, the second separation structure IS2a is placed outside of the four SPADs, leaving a margin between the SPADs and the second separation structure IS2a.

The first separation structure IS1a may be located at the center of the unit pixel 200. The first separation structure IS1a may be a trench-type separation structure. The first separation structure IS1a may have a shape extending toward the connection regions (IC12a, IC13a, IC24a, and IC34a) from one surface on which the arriving light RL is incident.

According to an embodiment, the first separation structure IS1a may overlap the connection regions IC12a, IC13a, IC24a, and IC34a. The first separation structure IS1a may be located between two adjacent biasing nodes (e.g., BN1a and BN2a). Since the first separation structure IS1a is located between the two adjacent biasing nodes, a movement of charges between the two adjacent biasing nodes may be partially isolated.

According to an embodiment, the first separation structure IS1a may extend toward the connection regions IC12a, IC13a, IC24a, and IC34a from the one surface on which the arriving light RL is incident.

The second separation structure IS2a may surround the four adjacent SPADs (SPAD1a, SPAD2a, SPAD3a, and SPAD4a). In the example, the second separation structure IS2a may be disposed external to the four adjacent SPADs (SPAD1a, SPAD2a, SPAD3a, and SPAD4a). In addition, adjacent unit pixels 200 may be separated from each other by the second separation structure IS2a.

According to an embodiment, the second separation structure IS2a may extend from the one surface on which the arriving light RL is incident to an opposite surface opposite to the one surface. In addition, the second separation structure IS2a may include a deep trench structure extending from the opposite surface toward the one surface.

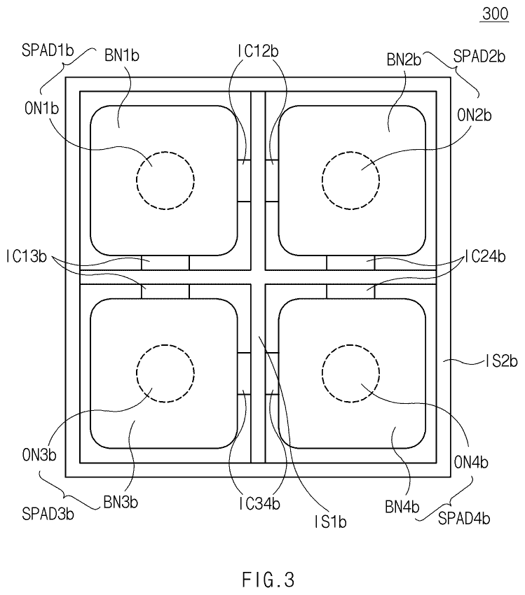

FIG. 3 is a view illustrating an embodiment of a unit pixel 300 included in the pixel array illustrated in FIG. 1.

Similar to the unit pixel 200 of FIG. 2, the unit pixel 300 of FIG. 3 is a plan view, taken from the direction of the incident light on the pixel array.

The unit pixel 300 may include a first SPAD (SPAD1b), a second SPAD (SPAD2b), a third SPAD (SPAD3b), and a fourth SPAD (SPAD4b) that are arranged in a 2×2 matrix including two rows and two columns.

Each of the SPADs may include a biasing node that receives a bias voltage and an output node that outputs a voltage pulse.

The first SPAD (SPAD1b) may include a first biasing node BN1b and a first output node ON1b. The second SPAD (SPAD2b) may include a second biasing node BN2b and a second output node ON2b. The third SPAD (SPAD3b) may include a third biasing node BN3b and a third output node ON3b. The fourth SPAD (SPAD4b) may include a fourth biasing node BN4b and a fourth output node ON4b.

In addition, the unit pixel 300 may include a plurality of connection regions IC12b, IC13b, IC24b, and IC34b that connect the adjacent SPADs, SPAD1b, SPAD2b, SPAD3b, and SPAD4b.

The unit pixel 300 may include a first connection region IC12b that connects the first biasing node BN1b and the second biasing node BN2b, a second connection region IC13b that connects the first biasing node BN1b and the third biasing node BN3b, a third connection region IC24b that connects the second biasing node BN2b and the fourth biasing node BN4b, and a fourth connection region IC34b that connects the third biasing node BN3b and the fourth biasing node BN4b.

The unit pixel 300 may include a first separation structure IS1b located at the center and a second separation structure IS2b surrounding the SPADs (SPAD1b, SPAD2b, SPAD3b, and SPAD4b). The second separation structure IS2b may be located external to the SPADs (SPAD1b, SPAD2b, SPAD3b, and SPAD4b).

While the characteristics of the SPADs (SPAD1b, SPAD2b, SPAD3b, and SPAD4b), the connection regions IC12b, IC13b, IC24b, and IC34b, and the separation structures IS1b and IS2b have been already described with reference to FIG. 2, such description can be applied to the unit pixel 300 as shown in FIG. 3. In the below, the differences from those discussed with reference to the example as shown in FIG. 2 will be mainly described.

The SPADs (SPAD1b, SPAD2b, SPAD3b, and SPAD4b) included in the unit pixel 300 of FIG. 3 may include the biasing nodes (BN1b, BN2b, BN3b, and BN4b) having a rounded rectangular shape and the output nodes (ON1b, ON2b, ON3b, and ON4b) having a circular shape.

Since the biasing nodes (BN1b, BN2b, BN3b, and BN4b) have a rounded rectangular shape, the areas occupied by the biasing nodes (BN1b, BN2b, BN3b, and BN4b) in the unit pixel 300 may be increased when compared to the areas occupied by biasing nodes having a circular shape.

As the areas of the biasing nodes BN1b, BN2b, BN3b, and BN4b are increased, the regions to which a reverse bias voltage is provided in the SPADs may be increased, and thus a photon may be easily detected. In addition, by changing the shapes of the biasing nodes BN1b, BN2b, BN3b, and BN4b, the electric field formed inside the SPADs SPAD1b, SPAD2b, SPAD3b, and SPAD4b by the reverse bias voltage may be adjusted to control detection of a photon.

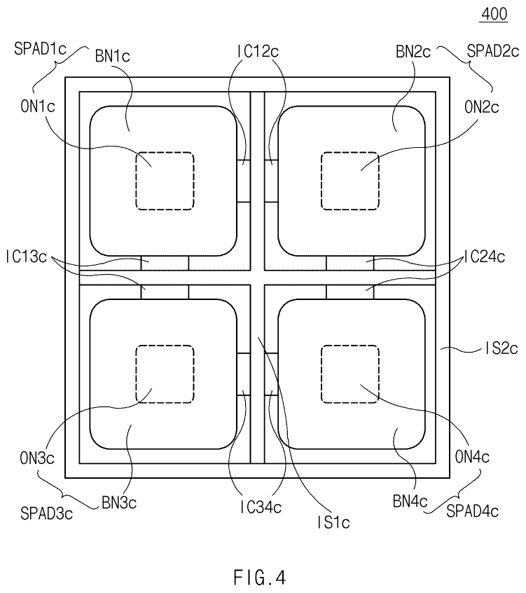

FIG. 4 is a view illustrating an embodiment of a unit pixel 400 included in the pixel array illustrated in FIG. 1.

Similar to the unit pixel 200 of FIG. 2, the unit pixel 400 of FIG. 4 is a plan view, taken from the direction of the incident light on the pixel array.

The unit pixel 400 may include a first SPAD (SPAD1c), a second SPAD (SPAD2c), a third SPAD (SPAD3c), and a fourth SPAD (SPAD4c) arranged in a 2×2 matrix including two rows and two columns.

Each of the SPADs may include a biasing node that receives a bias voltage and an output node that outputs a voltage pulse.

The first SPAD SPAD1c may include a first biasing node BN1c and a first output node ON1c. The second SPAD SPAD2c may include a second biasing node BN2c and a second output node ON2c. The third SPAD SPAD3c may include a third biasing node BN3c and a third output node ON3c. The fourth SPAD SPAD4c may include a fourth biasing node BN4c and a fourth output node ON4c.

In addition, the unit pixel 400 may include a plurality of connection regions IC12c, IC13c, IC24c, and IC34c that connect the adjacent SPADs SPAD1c, SPAD2c, SPAD3c, and SPAD4c.

The unit pixel 400 may include a first connection region IC12c that connects the first biasing node BN1c and the second biasing node BN2c, a second connection region IC13c that connects the first biasing node BN1c and the third biasing node BN3c, a third connection region IC24c that connects the second biasing node BN2c and the fourth biasing node BN4c, and a fourth connection region IC34c that connects the third biasing node BN3c and the fourth biasing node BN4c.

The unit pixel 400 may include a first separation structure IS1c located at the center and a second separation structure IS2c surrounding the SPADs (SPAD1c, SPAD2c, SPAD3c, and SPAD4c). The second separation structure IS2c may be located external to the SPADs (SPAD1c, SPAD2c, SPAD3c, and SPAD4c).

The characteristics of the SPADs (SPAD1c, SPAD2c, SPAD3c, and SPAD4c), the connection regions IC12c, IC13c, IC24c, and IC34c, and the separation structures IS1c and IS2c included in the unit pixel 400 will be described focusing on the characteristics different from FIG. 2.

The SPADs SPAD1c, SPAD2c, SPAD3c, and SPAD4c included in the unit pixel 400 of FIG. 4 may include the biasing nodes BN1c, BN2c, BN3c, and BN4c having a rounded rectangular shape and the output nodes ON1c, ON2c, ON3c, and ON4c having a rounded rectangular shape.

When the width of the output node ON1b of FIG. 3 is equal to the width of the output node ON1c of FIG. 4, the area of the output node ON1c of FIG. 4 may be greater than the area of the output node ON1b of FIG. 3.

The areas of the output nodes ON1c, ON2c, ON3c, and ON4c may correspond to the area of an active region capable of detecting a photon, and as the areas of the output nodes ON1c, ON2c, ON3c, and ON4c are increased, the sensitivity may be improved. In contrast, as the areas of the output nodes ON1c, ON2c, ON3c, and ON4c are increased, the possibility of noise due to background noise may be increased, and the possibility of an edge breakdown phenomenon may be increased.

FIG. 5 is a view illustrating an embodiment of a cross-sectional structure taken along a first cutting line A-A′ of FIG. 2.

Referring to FIG. 5, a first cross-sectional structure 200a taken along the first cutting line A-A′ of FIG. 2 is illustrated.

The first cross-sectional structure 200a of FIG. 5 will be described on the premise that the first cross-sectional structure 200a is formed on an N-type substrate (N-substrate) doped with an N-type impurity (e.g., Group V element). However, other implementations are also possible. For example, the first cross-sectional structure 200a may be formed in a well region doped with an N-type impurity inside a P-type substrate doped with a P-type impurity (e.g., Group III element).

Referring to the first cross-sectional structure 200a, the unit pixel may include a micro lens ML located on the N-type substrate (N-substrate) and a grid structure GS located between adjacent micro lenses ML.

In addition, the unit pixel may include a first output node 1000a, a second output node 1000b, a first connection region 1100, a first biasing node 1200a, a second biasing node 1200b, a first separation structure 1300, and a second separation structure 1400, which are located inside the N-type substrate (N-substrate).

The micro lens ML may be formed in a hemispherical shape on the N-type substrate (N-substrate) and may increase light gathering power for incident light, thereby improving light receiving efficiency (the amount of received light per unit area).

The micro lens ML may further include an overcoating layer (not illustrated) that prevents diffuse reflection of the incident light.

The grid structure GS may be located between micro lenses ML included in adjacent unit pixels. A cross-talk phenomenon in which the incident light is introduced between the adjacent unit pixels may be prevented by the grid structure GS.

According to an embodiment, the grid structure GS may include a metallic material such as tungsten. According to an embodiment, the grid structure GS may include an air layer including an air and a capping film, and the capping film may include a silicon oxide film.

The N-type substrate (N-substrate) may be or include a silicon substrate used for semiconductor processing. The N-type substrate (N-substrate) may include a first surface on which the arriving light RL is incident and a second surface opposite to the first surface. In some implementations, the N-type substrate (N-substrate) may include a N-type bulk substrate. In some implementations, the N-type substrate (N-substrate) may be obtained by growing an N-type epitaxial layer on an N-type bulk substrate or a P-type bulk substrate.

The first output node 1000a and the second output node 1000b may be located on the second surface of the N-type substrate (N-substrate) that is opposite to the first surface on which the light is incident.

The first output node 1000a and the second output node 1000b may be regions doped with a P-type impurity. The first output node 1000a and the second output node 1000b may detect holes 1001 generated in the unit pixel.

Due to a photon of the arriving light RL for the unit pixel, photoelectric conversion may occur, and electrons and the holes 1001 may be generated. FIG. 5 illustrates an example that three holes 1001 are generated at a specific location by the arriving light RL. However, other implementations are also possible. At least one hole 1001 may be generated at any location in the unit pixel, and an avalanche process may be performed.

The first output node 1000a and the second output node 1000b may detect the holes 1001 in the form of a voltage pulse.

According to an embodiment, the first output node 1000a and the second output node 1000b may further include a plurality of P-type impurity regions having different concentrations.

The first biasing node 1200a may have a shape that surrounds the first output node 1000a. In the example, the first biasing node 1200a may surround the first output node 1000a while being spaced apart from the first output node 1000a. The first biasing node 1200a may have a shape that extends from the second surface of the N-type substrate (N-substrate) toward the first surface of the N-type substrate (N-substrate).

The first biasing node 1200a may include a first high-concentration region 1210a, a first intermediate region 1220a, and a first well region 1230a. The first high-concentration region 1210a, the first intermediate region 1220a, and the first well region 1230a may be N-type doping regions.

The first high-concentration region 1210a may be a region having the highest concentration among the regions included in the first biasing node 1200a. The first intermediate region 1220a may be located between the first high-concentration region 1210a and the first well region 1230a and may have a concentration higher than the impurity concentration of the N-type substrate (N-substrate). The first well region 1230a may have a concentration higher than the impurity concentration of the N-type substrate (N-substrate).

According to an embodiment, the doping concentration may be decreased in the order of the first high-concentration region 1210a, the first intermediate region 1220a, the first well region 1230a, and the N-type substrate.

Since the concentrations of the regions included in the first biasing node 1200a are decreased from the second surface toward the first surface of the N-type substrate, the electric field (or, reverse bias) due to the bias voltage provided to the first biasing node 1200a may affect a deeper location of the N-type substrate.

Accordingly, the avalanche process may be performed even by a photon reaching a deep location of the N-type substrate, and thus the sensitivity of the SPAD may be improved.

The second biasing node 1200b may include a second high-concentration region 1210b, a second intermediate region 1220b, and a second well region 1230b. According to an embodiment, the doping concentration of an N-type impurity may be decreased in the order of the second high-concentration region 1210b, the second intermediate region 1220b, the second well region 1230b, and the N-type substrate.

The first biasing node 1200a and the second biasing node 1200b may be electrically connected by the first connection region 1100. The first connection region 1100 may be a region doped with an N-type impurity and may have the same impurity concentration as the first well region 1230a or the second well region 1230b.

The thickness of a connection region (e.g., 1100) may be the length of the connection region (e.g., 1100) in a direction perpendicular to the first surface of the N-type substrate, and the width of the connection region (e.g., 1100) may be the length of the connection region (e.g., 1100) in a direction parallel to the first surface of the N-type substrate.

Likewise, the thickness of an output node (e.g., 1000a) may be the length of the output node (e.g., 1000a) in the direction perpendicular to the one surface of the N-type substrate, and the width of the output node (e.g., 1000a) may be the length of the output node (e.g., 1000a) in the direction parallel to the one surface of the N-type substrate.

In addition, the thickness of a biasing node (e.g., 1200a) may be the length of the biasing node (e.g., 1200a) in the direction perpendicular to the one surface of the N-type substrate, and the width of the biasing node (e.g., 1200a) may be the length of the biasing node (e.g., 1200a) in the direction parallel to the one surface of the N-type substrate.

Referring to FIG. 5, the width of the biasing node (e.g., 1200a) may be greater than the width of the connection region (e.g., 1100), and the thickness of the biasing node (e.g., 1200a) may be greater than the thickness of the connection region (e.g., 1100).

The preset voltage for determining whether to operate in the first mode or the second mode described above with reference to FIG. 2 may vary depending on the thickness and width of the first connection region 1100.

For example, as the thickness of the first connection region 1100 is increased, the potential due to the voltage provided to the first biasing node 1200a may be easily transferred to the second biasing node 1200b. Accordingly, as the thickness of the first connection region 1100 is increased, the preset voltage may be decreased, and the unit pixel may operate at a low bias voltage in the first mode.

Referring to the first cross-sectional structure 200a of FIG. 5, the first separation structure 1300 included in the unit pixel may include a first outer separation layer 1310 and a first inner separation layer 1320.

The first separation structure 1300 may separate the first biasing node 1200a and the second biasing node 1200b from each other and may prevent holes from moving between the first biasing node 1200a and the second biasing node 1200b.

The first outer separation layer 1310 included in the first separation structure 1300 may include a silicon oxide film, a silicon nitride film, or a poly silicon film.

The first inner separation layer 1320 may include a silicon oxide film, a silicon nitride film, a poly silicon film, a metal layer, or an air layer.

The first separation structure 1300 may be formed by making the one surface of the N-type substrate subject to patterning to form a deep trench and filling the trench with the first outer separation layer 1310 and the first inner separation layer 1320.

The first separation structure 1300 may be formed to have a smaller depth than the second separation structure 1400 with respect to the one surface of the N-type substrate such that the first connection region 1100 is capable of being formed.

Referring to the first cross-sectional structure 200a of FIG. 5, the second separation structure 1400 included in the unit pixel may include a second outer separation layer 1410, a second inner separation layer 1420, and a trench layer 1430.

The second separation structure 1400 may extend from one side to an opposite side of the N-type substrate to prevent holes from moving between the adjacent unit pixels. The second separation structure 1400 may be disposed to surround a plurality of SPADs included in the unit pixel. In the example, the second separation structure 1400 may be disposed external to the plurality of SPADs while being spaced apart from the plurality of SPADs.

The second outer separation layer 1410 included in the second separation structure 1400 may include at least one of a silicon oxide film, a silicon nitride film, or a poly silicon film.

The second inner separation layer 1420 may include at least one of a silicon oxide film, a silicon nitride film, a poly silicon film, a metal layer, or an air layer.

The trench layer 1430 may have a shape extending from the second surface of the N-type substrate toward the first surface of the N-type substrate. The trench layer 1430 may include at least one of a silicon oxide film, a silicon nitride film, a poly silicon film, a metal layer, or an air layer.

The second separation structure 1400 may be formed by making the one surface of the N-type substrate subject to patterning to form a deep trench and filling the trench with the second outer separation layer 1410 and the second inner separation layer 1420. In addition, the trench layer 1430 may be formed by making the opposite surface of the N-type substrate subject to patterning.

FIG. 6 is a view illustrating an embodiment of a cross-sectional structure taken along the first cutting line A-A′ of FIG. 2.

Referring to FIG. 6, a second cross-sectional structure 200b taken along the first cutting line A-A′ of FIG. 2 is illustrated.

The second cross-sectional structure 200b of FIG. 6 will be described on the premise that the second cross-sectional structure 200b is formed on a P-type substrate (P-substrate) doped with a P-type impurity (e.g., Group III element). However, other implementations are also possible, and the second cross-sectional structure 200b may be a structure formed in a well region doped with a P-type impurity inside an N-type substrate doped with an N-type impurity (e.g., Group V element).

Referring to the second cross-sectional structure 200b, the unit pixel may include a micro lens ML located on the P-type substrate (P-substrate) and a grid structure GS located between adjacent micro lenses ML.

In addition, the unit pixel may include a first output node 2000a, a second output node 2000b, a first connection region 2100, a first biasing node 2200a, a second biasing node 2200b, a first separation structure 2300, and a second separation structure 2400, which are inside the P-type substrate (P-substrate).

The second cross-sectional structure 200b of FIG. 6 is substantially the same as the first cross-sectional structure 200a of FIG. 5 except for the impurity doping type, and therefore repetitive description will be omitted and the differences from the example as shown in FIG. 5 are mainly discussed.

The P-type substrate (P-substrate) may be a silicon substrate used for semiconductor processing. The P-type substrate (P-substrate) may include one surface on which the arriving light RL is incident and an opposite surface opposite to the one surface. The P-type substrate (P-substrate) may be a P-type bulk substrate, a substrate in which a P-type epitaxial layer is grown on an N-type bulk substrate, or a substrate in which a P-type epitaxial layer is grown on a P-type bulk substrate.

The first output node 2000a and the second output node 2000b may be located on the second surface of the P-type substrate (P-substrate) that is opposite to the first surface on which the light is incident.

The first output node 2000a and the second output node 2000b may be regions doped with an N-type impurity. The first output node 2000a and the second output node 2000b may detect electrons 2001 generated in the unit pixel.

Due to a photon of the arriving light RL for the unit pixel, photoelectric conversion may occur, and the electrons 2001 and holes may be generated. FIG. 6 illustrates an example that three electrons 2001 are generated at a specific location by the arriving light RL. However, other implementations are also possible. At least one electron 2001 may be generated at any location in the unit pixel, and an avalanche process may be performed.

The first output node 2000a and the second output node 2000b may detect the electrons 2001 in the form of a voltage pulse.

The first biasing node 2200a may have a shape that surrounds the first output node 2000a and extends from the second, opposite surface of the P-type substrate (P-substrate) toward the first surface of the P-type substrate (P-substrate).

The first biasing node 2200a may include a first high-concentration region 2210a, a first intermediate region 2220a, and a first well region 2230a. The first high-concentration region 2210a, the first intermediate region 2220a, and the first well region 2230a may be P-type doping regions.

According to an embodiment, the doping concentration may be decreased in the order of the first high-concentration region 2210a, the first intermediate region 2220a, the first well region 2230a, and the P-type substrate.

The second biasing node 2200b may have a shape that surrounds the second output node 2000b. In the example, the second biasing node 2200b may surround the second output node 2000b while being spaced apart from the second output node 2000b. The second biasing node 2200b may have a shape that extends from the second surface of the P-type substrate (P-substrate) toward the first surface of the P-type substrate (P-substrate).

The second biasing node 2200b may include a second high-concentration region 2210b, a second intermediate region 2220b, and a second well region 2230b. The second high-concentration region 2210b, the second intermediate region 2220b, and the second well region 2230b may be P-type doping regions.

According to an embodiment, the doping concentration may be decreased in the order of the second high-concentration region 2210b, the second intermediate region 2220b, the second well region 2230b, and the P-type substrate.

The first biasing node 2200a and the second biasing node 2200b may be electrically connected by the first connection region 2100. The first connection region 2100 may be a region doped with a P-type impurity and may have the same impurity concentration as the first well region 2230a or the second well region 2230b.

Referring to FIG. 6, the unit pixel may include the first separation structure 2300 and the second separation structure 2400. The first separation structure 2300 may prevent charges from moving between adjacent biasing nodes.

A first outer separation layer 2310 included in the first separation structure 2300 may include at least one of a silicon oxide film, a silicon nitride film, or a poly silicon film.

A first inner separation layer 2320 may include at least one of a silicon oxide film, a silicon nitride film, a poly silicon film, a metal layer, or an air layer.

The second separation structure 2400 may include a second outer separation layer 2410, a second inner separation layer 2420, and a trench layer 2430.

The second separation structure 2400 may extend from one side to an opposite side of the P-type substrate to prevent electrons from moving between adjacent unit pixels. The second separation structure 2400 may be disposed to surround a plurality of SPADs included in the unit pixel. In the example, the second separation structure 2400 may be disposed external to the plurality of SPADs while being spaced apart from the plurality of SPADs.

The second outer separation layer 2410 included in the second separation structure 2400 may include at least one of a silicon oxide film, a silicon nitride film, or a poly silicon film.

The second inner separation layer 2420 may include at least one of a silicon oxide film, a silicon nitride film, a poly silicon film, a metal layer, or an air layer.

The trench layer 2430 may have a shape extending from the second surface of the P-type substrate toward the first surface of the P-type substrate. The trench layer 2430 may include at least one of a silicon oxide film, a silicon nitride film, a poly silicon film, a metal layer, or an air layer.

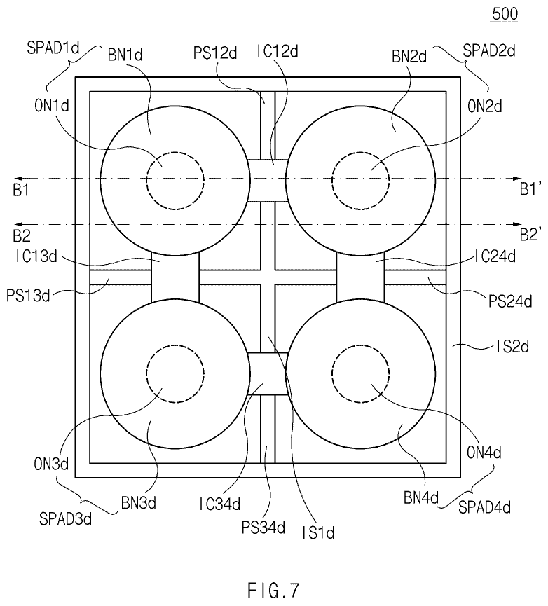

FIG. 7 is a view illustrating an embodiment of a unit pixel included in the pixel array illustrated in FIG. 1.

FIG. 7 illustrates a plan view of the unit pixel 500, taken from the direction of the incident light on the pixel array.

Referring to FIG. 7, the unit pixel 500 included in the pixel array may include a first SPAD (SPAD1d), a second SPAD (SPAD2d), a third SPAD (SPAD3d), and a fourth SPAD (SPAD4d), which are arranged in a 2×2 matrix.

The first SPAD (SPAD1d) may include a first biasing node BN1d and a first output node ON1d. The second SPAD (SPAD2d) may include a second biasing node BN2d and a second output node ON2d. The third SPAD (SPAD3d) may include a third biasing node BN3d and a third output node ON3d. The fourth SPAD (SPAD4d) may include a fourth biasing node BN4d and a fourth output node ON4d.

The unit pixel 500 illustrated in FIG. 7 may include connection regions that are disposed between two adjacent biasing nodes and that electrically connect the two adjacent biasing nodes.

The unit pixel 500 may include a first connection region IC12d that connects the first biasing node BN1d and the second biasing node BN2d, a second connection region IC13d that connects the first biasing node BN1d and the third biasing node BN3d, a third connection region IC24d that connects the second biasing node BN2d and the fourth biasing node BN4d, and a fourth connection region IC34d that connects the third biasing node BN3d and the fourth biasing node BN4d.

According to the embodiment of FIG. 7, the unit pixel 500 may include a first separation structure IS1d located between the four SPADs (SPAD1d, SPAD2d, SPAD3d, and SPAD4d) and a second separation structure IS2d surrounding the four SPADs (SPAD1d, SPAD2d, SPAD3d, and SPAD4d). The second separation structure Is2d may be disposed external to the four SPADs (SPAD1d, SPAD2d, SPAD3d, and SPAD4d).

The first to fourth connection regions IC12d, IC13d, IC24d, and IC34d may be disposed between the first separation structure IS1d and the second separation structure IS2d. The first to fourth connection regions IC12d, IC13d, IC24d, and IC34d may be in contact with the first separation structure IS1d and the second separation structure IS2d.

Unlike in the embodiments of FIGS. 2 to 4, the first to fourth connection regions IC12d, IC13d, IC24d, and IC34d may not overlap the first separation structure IS1d. Thus, the first separation structure IS1d may not be formed in the regions where the first to fourth connection regions IC12d, IC13d, IC24d, and IC34d are formed.

The first separation structure IS1d may extend from one surface toward an opposite surface of the substrate on which the four SPADs SPAD1d, SPAD2d, SPAD3d, and SPAD4d are formed and may prevent electrons or holes from moving in the regions where the first to fourth connection regions IC12d, IC13d, IC24d, and IC34d are not formed.

The second separation structure IS2d may include protruding structures PS12d, PS13d, PS24d, and PS34d extending from edges of the second separation structure IS2d toward the first to fourth connection regions IC12d, IC13d, IC24d, and IC34d. The protruding structures PS12d, PS13d, PS24d, and PS34d may extend from one surface toward an opposite surface of the substrate on which the four SPADs SPAD1d, SPAD2d, SPAD3d, and SPAD4d are formed and may prevent electrons or holes from moving in the regions where the first to fourth connection regions IC12d, IC13d, IC24d, and IC34d are not formed.

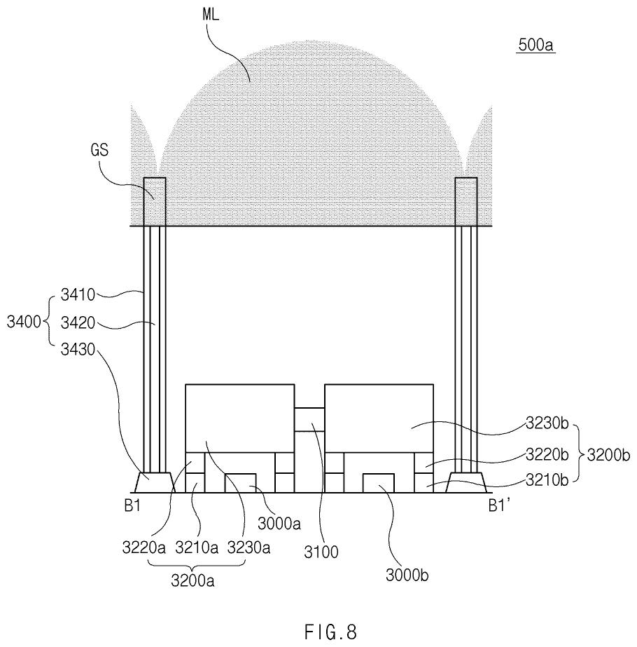

FIG. 8 is a view illustrating an embodiment of a cross-sectional structure taken along a second cutting line B1-B1′ of FIG. 7.

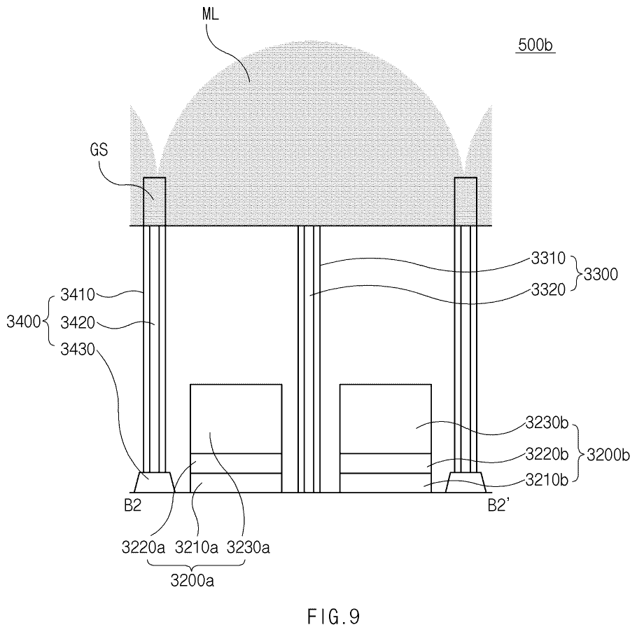

FIG. 9 is a view illustrating an embodiment of a cross-sectional structure taken along a third cutting line B2-B2′ of FIG. 7.

Referring to FIG. 8, a second cross-sectional structure 500a taken along the second cutting line B1-B1′ of FIG. 7 is illustrated.

Referring to FIG. 9, a third cross-sectional structure 500b taken along the third cutting line B2-B2′ of FIG. 7 is illustrated.

The cross-sectional structure of a unit pixel according to an embodiment of the present disclosure will be described with reference to FIGS. 8 and 9.

The second cross-sectional structure 500a of FIG. 8 and the third cross-sectional structure 500b of FIG. 9 will be described on the premise that the second cross-sectional structure 500a and the third cross-sectional structure 500b are structures formed on an N-type substrate (N-substrate) doped with an N-type impurity (e.g., Group V element). However, other implementations are also possible. For example, the second cross-sectional structure 500a and the third cross-sectional structure 500b may be formed in a well region doped with an N-type impurity inside a P-type substrate doped with a P-type impurity (e.g., Group III element).

The unit pixel may include a micro lens ML located on the N-type substrate (N-substrate) and a grid structure GS located between adjacent micro lenses ML.

In the example, the unit pixel may include a first output node 3000a, a second output node 3000b, a first connection region 3100, a first biasing node 3200a, a second biasing node 3200b, a first separation structure 3300, and a second separation structure 3400, which are disposed inside the N-type substrate (N-substrate).

The micro lens ML and the grid structure GS are substantially the same as the components described above with reference to FIGS. 5 and 6, and therefore repetitive description will be omitted.

The N-type substrate (N-substrate) may be a silicon substrate used for semiconductor processing. The N-type substrate (N-substrate) may include a first surface on which the arriving light RL is incident and a second, opposite surface opposite to the first surface. The N-type substrate (N-substrate) may be an N-type bulk substrate, a substrate in which an N-type epitaxial layer is grown on a P-type bulk substrate, or a substrate in which an N-type epitaxial layer is grown on an N-type bulk substrate.

The first output node 3000a and the second output node 3000b may be located on the second surface of the N-type substrate (N-substrate).

The first output node 3000a and the second output node 3000b may be regions doped with a P-type impurity. The first output node 3000a and the second output node 3000b may detect holes 3000 generated in the unit pixel in the form of a voltage pulse.

According to an embodiment, the first output node 3000a and the second output node 3000b may further include a plurality of P-type impurity regions having different concentrations from one another.

The first biasing node 3200a may have a shape that surrounds the first output node 3000a. In the example, the first biasing node 3200a may surround the first output node 3000a while being spaced apart from the first output node 3000a. The first biasing node 3200a may have a shape that extends from the second surface of the N-type substrate (N-substrate) toward the first surface of the N-type substrate (N-substrate).

The first biasing node 3200a may include a first high-concentration region 3210a, a first intermediate region 3220a, and a first well region 3230a. The first high-concentration region 3210a, the first intermediate region 3220a, and the first well region 3230a may be N-type doping regions.

The first high-concentration region 3210a may be a region having the highest concentration among the regions included in the first biasing node 3200a. The first intermediate region 3220a may be located between the first high-concentration region 3210a and the first well region 3230a and may have a concentration higher than the impurity concentration of the N-type substrate (N-substrate). The first well region 3230a may have a concentration higher than the impurity concentration of the N-type substrate (N-substrate).

According to an embodiment, the doping concentration may be decreased in the order of the first high-concentration region 3210a, the first intermediate region 3220a, the first well region 3230a, and the N-type substrate.

The second biasing node 3200b may include a second high-concentration region 3210b, a second intermediate region 3220b, and a second well region 3230b. According to an embodiment, the doping concentration of an N-type impurity may be decreased in the order of the second high-concentration region 3210b, the second intermediate region 3220b, the second well region 3230b, and the N-type substrate.

The first biasing node 3200a and the second biasing node 3200b may be electrically connected by the first connection region 3100. The first connection region 3100 may be a region doped with an N-type impurity and may have the same impurity concentration as the first well region 3230a or the second well region 3230b.

Referring to the second cross-sectional structure 500a and the third cross-sectional structure 500b, the first separation structure 3300 included in the unit pixel may include a first outer separation layer 3310 and a first inner separation layer 3320.

The first separation structure 3300 may separate the first biasing node 3200a and the second biasing node 3200b from each other and may prevent holes from moving between the first biasing node 3200a and the second biasing node 3200b.

The first outer separation layer 3310 included in the first separation structure 3300 may include a silicon oxide film, a silicon nitride film, or a poly silicon film.

The first inner separation layer 3320 may include a silicon oxide film, a silicon nitride film, a poly silicon film, a metal layer, or an air layer.

The first separation structure 3300 may be formed by making the one surface of the N-type substrate subject to patterning to form a deep trench to the opposite surface of the N-type substrate and filling the trench with the first outer separation layer 3310 and the first inner separation layer 3320.

Referring to the second cross-sectional structure 500a, the first separation structure 3300 may not be formed in the region where the first connection region 3100 is formed.

The thickness of the first connection region 3100 in a direction perpendicular to the one surface of the N-type substrate may be smaller than the thickness of the first well region 3230a or the second well region 3230b in the direction perpendicular to the one surface of the N-type substrate. The preset voltage for determining whether to operate in the first mode or the second mode described above with reference to FIG. 2 may vary depending on the thickness of the first connection region 3100.

The second separation structure 3400 included in the unit pixel may include a second outer separation layer 3410, a second inner separation layer 3420, and a trench layer 3430.

The second separation structure 3400 may extend from one side to an opposite side of the N-type substrate to prevent holes from moving between adjacent unit pixels. The second separation structure 3400 may be disposed to surround a plurality of SPADs included in the unit pixel. The second separation structure 3400 may be disposed external to the plurality of SPADs included in the unit pixel.

The second outer separation layer 3410 included in the second separation structure 3400 may include a silicon oxide film, a silicon nitride film, or a poly silicon film.

The second inner separation layer 3420 may include a silicon oxide film, a silicon nitride film, a poly silicon film, a metal layer, or an air layer.

The trench layer 3430 may have a shape extending from the second surface of the N-type substrate toward the first surface of the N-type substrate. The trench layer 3430 may include at least one of a silicon oxide film, a silicon nitride film, a poly silicon film, a metal layer, or an air layer.

The second separation structure 3400 may be formed by making the one surface of the N-type substrate subject to patterning to form a deep trench and filling the trench with the second outer separation layer 3410 and the second inner separation layer 3420. In addition, the trench layer 3430 may be formed by making the opposite surface of the N-type substrate subject to patterning.

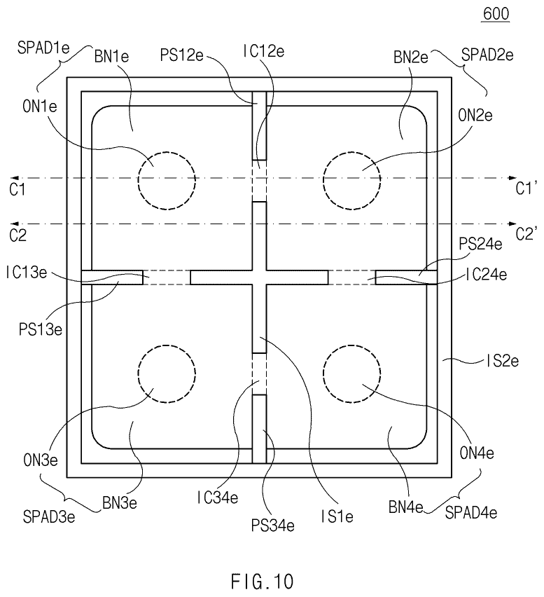

FIG. 10 is a view illustrating an embodiment of a unit pixel included in the pixel array illustrated in FIG. 1.

FIG. 10 illustrates a plan view of the unit pixel 600, taken from the direction of the incident light on the pixel array.

Referring to FIG. 10, the unit pixel 600 included in the pixel array may include a first SPAD SPAD1e, a second SPAD SPAD2e, a third SPAD SPAD3e, and a fourth SPAD SPAD4e arranged in a 2×2 matrix.

The first SPAD SPAD1e may include a first biasing node BN1e and a first output node ON1e. The second SPAD SPAD2e may include a second biasing node BN2e and a second output node ON2e. The third SPAD SPAD3e may include a third biasing node BN3e and a third output node ON3e. The fourth SPAD SPAD4e may include a fourth biasing node BN4e and a fourth output node ON4e.

The first to fourth biasing nodes BN1e, BN2e, BN3e, and BN4e may have a rectangular shape with one rounded corner. In addition, the first to fourth output nodes ON1e, ON2e, ON3e, and ON4e may have a circular shape.

Since the first to fourth biasing nodes BN1e, BN2e, BN3e, and BN4e have a rectangular shape with one rounded corner, the region to which a bias voltage is applied may be greater than those of the unit pixels (e.g., 500 in FIG. 7) of the other embodiments.

The unit pixel 600 illustrated in FIG. 10 may include connection regions that are disposed between two adjacent biasing nodes and that electrically connect the two adjacent biasing nodes.

The unit pixel 600 may include a first connection region IC12e that connects the first biasing node BN1e and the second biasing node BN2e, a second connection region IC13e that connects the first biasing node BN1e and the third biasing node BN3e, a third connection region IC24e that connects the second biasing node BN2e and the fourth biasing node BN4e, and a fourth connection region IC34e that connects the third biasing node BN3e and the fourth biasing node BN4e.

According to the embodiment of FIG. 10, the unit pixel 600 may include a first separation structure IS1e located between the four SPADs (SPAD1e, SPAD2e, SPAD3e, and SPAD4e) and a second separation structure IS2e surrounding the four SPADs (SPAD1e, SPAD2e, SPAD3e, and SPAD4e). In the example, the second separation structure IS2e may be disposed external to four SPADs (SPAD1e, SPAD2e, SPAD3e, and SPAD4e).

The first to fourth connection regions IC12e, IC13e, IC24e, and IC34e may be disposed between the first separation structure IS1e and the second separation structure IS2e. The first to fourth connection regions IC12e, IC13e, IC24e, and IC34e may be in contact with the first separation structure IS1e and the second separation structure IS2e.

Unlike in the embodiments of FIGS. 2 to 4, the first to fourth connection regions IC12e, IC13e, IC24e, and IC34e may not overlap the first separation structure IS1e. In other words, the first separation structure IS1e may not be formed in the regions where the first to fourth connection regions IC12e, IC13e, IC24e, and IC34e are formed.

In addition, the width of one side of the first to fourth connection regions IC12e, IC13e, IC24e, and IC34e may be equal to the width of the first separation structure IS1e or the second separation structure IS2e.

The first separation structure IS1e may extend from one surface toward an opposite surface of the substrate on which the four SPADs SPAD1e, SPAD2e, SPAD3e, and SPAD4e are formed and may prevent electrons or holes from moving in the regions where the first to fourth connection regions IC12e, IC13e, IC24e, and IC34e are not formed.

The second separation structure IS2e may include protruding structures PS12e, PS13e, PS24e, and PS34e extending from edges of the second separation structure IS2e toward the first to fourth connection regions IC12e, IC13e, IC24e, and IC34e. The protruding structures PS12e, PS13e, PS24e, and PS34e may extend from the one surface toward the opposite surface of the substrate on which the four SPADs SPAD1e, SPAD2e, SPAD3e, and SPAD4e are formed and may prevent electrons or holes from moving in the regions where the first to fourth connection regions IC12e, IC13e, IC24e, and IC34e are not formed.

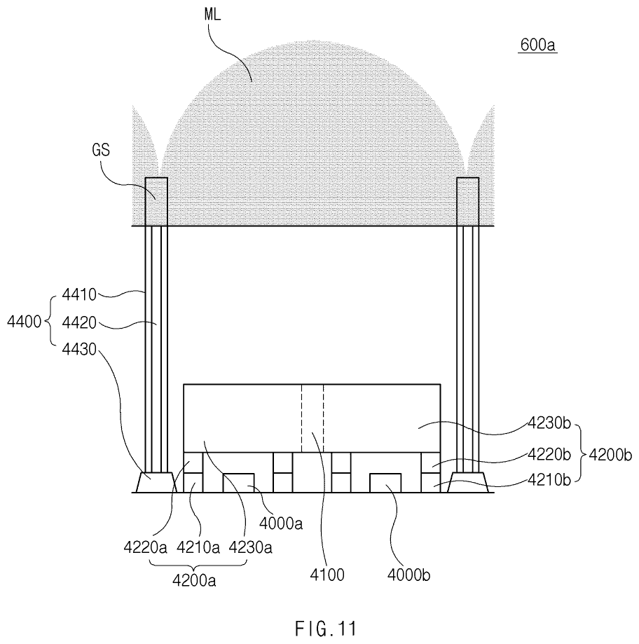

FIG. 11 is a view illustrating an embodiment of a cross-sectional structure taken along a fourth cutting line C1-C1′ of FIG. 10.

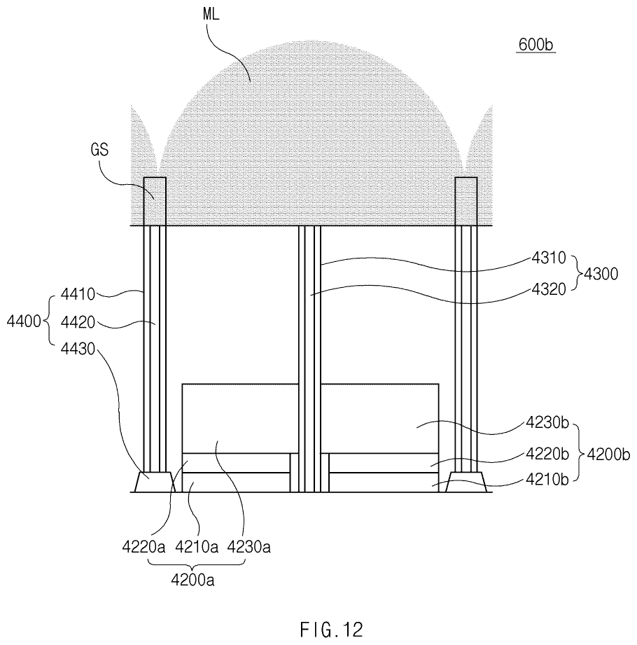

FIG. 12 is a view illustrating an embodiment of a cross-sectional structure taken along a fifth cutting line C2-C2′ of FIG. 10.

Referring to FIG. 11, a fourth cross-sectional structure 600a taken along the fourth cutting line C1-C1′ of FIG. 10 is illustrated.

Referring to FIG. 12, a fifth cross-sectional structure 600b taken along the fifth cutting line C2-C2′ of FIG. 10 is illustrated.

The cross-sectional structure of a unit pixel according to an embodiment of the present disclosure will be described with reference to FIGS. 11 and 12.

The fourth cross-sectional structure 600a of FIG. 11 and the fifth cross-sectional structure 600b of FIG. 12 will be described on the premise that the fourth cross-sectional structure 600a and the fifth cross-sectional structure 600b are structures formed on an N-type substrate (N-substrate) doped with an N-type impurity (e.g., Group V element). However, other implementations are also possible. For example, the fourth cross-sectional structure 600a and the fifth cross-sectional structure 600b may be structures formed in a well region doped with an N-type impurity inside a P-type substrate doped with a P-type impurity (e.g., Group III element).

The unit pixel may include a micro lens ML located on the N-type substrate (N-substrate) and a grid structure GS located between adjacent micro lenses ML.

In addition, the unit pixel may include a first output node 4000a, a second output node 4000b, a first connection region 4100, a first biasing node 4200a, a second biasing node 4200b, a first separation structure 4300, and a second separation structure 4400 inside the N-type substrate (N-substrate).

The micro lens ML and the grid structure GS are substantially the same as the components described above with reference to FIGS. 5 and 6, and therefore repetitive description will be omitted.

The N-type substrate (N-substrate) may be a silicon substrate used for semiconductor processing. The N-type substrate (N-substrate) may include one surface on which the arriving light RL is incident and an opposite surface opposite to the one surface. The N-type substrate (N-type substrate) may be an N-type bulk substrate, a substrate in which an N-type epitaxial layer is grown on a P-type bulk substrate, or a substrate in which an N-type epitaxial layer is grown on an N-type bulk substrate.

The first output node 4000a and the second output node 4000b may be located on the opposite surface of the N-type substrate (N-substrate).

The first output node 4000a and the second output node 4000b may be regions doped with a P-type impurity. The first output node 4000a and the second output node 4000b may detect holes generated in the unit pixel in the form of a voltage pulse.

According to an embodiment, the first output node 4000a and the second output node 4000b may further include a plurality of P-type impurity regions having different concentrations.

The first biasing node 4200a may have a shape that surrounds the first output node 4000a. In the example, the first biasing node 4200a may surround the first output node 1000a while being spaced apart from the first output node 4000a. The first biasing node 4200a may have a shape that extends from the second, opposite surface of the N-type substrate (N-substrate) toward the first surface of the N-type substrate (N-substrate).

The first biasing node 4200a may include a first high-concentration region 4210a, a first intermediate region 4220a, and a first well region 4230a. The first high-concentration region 4210a, the first intermediate region 4220a, and the first well region 4230a may be N-type doping regions.

The first high-concentration region 4210a may be a region having the highest concentration among the regions included in the first biasing node 4200a. The first intermediate region 4220a may be located between the first high-concentration region 4210a and the first well region 4230a and may have a concentration higher than the impurity concentration of the N-type substrate (N-substrate). The first well region 4230a may have a concentration higher than the impurity concentration of the N-type substrate (N-substrate).

According to an embodiment, the doping concentration may be decreased in the order of the first high-concentration region 4210a, the first intermediate region 4220a, the first well region 4230a, and the N-type substrate.

The second biasing node 4200b may include a second high-concentration region 4210b, a second intermediate region 4220b, and a second well region 4230b. According to an embodiment, the doping concentration of an N-type impurity may be decreased in the order of the second high-concentration region 4210b, the second intermediate region 4220b, the second well region 4230b, and the N-type substrate.

The first biasing node 4200a and the second biasing node 4200b may be electrically connected by the first connection region 4100. The first connection region 4100 may be a region doped with an N-type impurity and may have the same impurity concentration as the first well region 4230a or the second well region 4230b.

The thickness of the first connection region 4100 in a direction perpendicular to the one surface of the N-type substrate may be equal to the thickness of the first well region 4230a or the second well region 4230b in the direction perpendicular to the one surface of the N-type substrate.

When the thickness of the first connection region 4100 is equal to the thickness of the first well region 4230a or the second well region 4230b, a bias voltage provided to one of the first well region 4230a and the second well region 4230b may easily affect the other one of the first well region 4230a and the second well region 4230b. Accordingly, the preset voltage for determining whether to operate in the first mode or the second mode may be lowered when compared to that in an embodiment in which the thickness of the first connection region 4100 is smaller than the thickness of the first well region 4230a or the second well region 4230b.

Referring to the fourth cross-sectional structure 600a and the fifth cross-sectional structure 600b, the first separation structure 4300 included in the unit pixel may include a first outer separation layer 4310 and a first inner separation layer 4320.

The first separation structure 4300 may separate the first biasing node 4200a and the second biasing node 4200b from each other and may prevent holes from moving between the first biasing node 4200a and the second biasing node 4200b.

The first outer separation layer 4310 included in the first separation structure 4300 may include a silicon oxide film, a silicon nitride film, or a poly silicon film.

The first inner separation layer 4320 may include a silicon oxide film, a silicon nitride film, a poly silicon film, a metal layer, or an air layer.

The first separation structure 4300 may be formed by making the one surface of the N-type substrate subject to patterning to form a deep trench to the opposite surface of the N-type substrate and filling the trench with the first outer separation layer 4310 and the first inner separation layer 4320.

Referring to the fourth cross-sectional structure 600a, the first separation structure 4300 may not be formed in the region where the first connection region 4100 is formed.

The second separation structure 4400 included in the unit pixel may include a second outer separation layer 4410, a second inner separation layer 4420, and a trench layer 4430.

The second separation structure 4400 may extend from one side to an opposite side of the N-type substrate to prevent holes from moving between adjacent unit pixels. The second separation structure 4400 may be disposed to surround a plurality of SPADs included in the unit pixel. The second separation structure 4400 may be disposed external to the plurality of SPADs included in the unit pixel.

The second outer separation layer 4410 included in the second separation structure 4400 may include a silicon oxide film, a silicon nitride film, or a poly silicon film.

The second inner separation layer 4420 may include a silicon oxide film, a silicon nitride film, a poly silicon film, a metal layer, or an air layer.

The trench layer 4430 may have a shape extending from the second surface of the N-type substrate toward the first surface of the N-type substrate. The trench layer 4430 may include at least one of a silicon oxide film, a silicon nitride film, a poly silicon film, a metal layer, or an air layer.

The second separation structure 4400 may be formed by making the one surface of the N-type substrate subject to patterning to form a deep trench and filling the trench with the second outer separation layer 4410 and the second inner separation layer 4420. In addition, the trench layer 4430 may be formed by making the opposite surface of the N-type substrate subject to patterning.

The image sensing device according to the embodiments of the present disclosure may adjust the bias voltage provided to the single-photon avalanche diode, thereby increasing the photon detection efficiency of the single-photon avalanche diode or increasing the resolution of the image sensing device.

In addition, the present disclosure may provide various effects that are directly or indirectly recognized.

Hereinabove, although the present disclosure has been described with reference to exemplary embodiments and the accompanying drawings, the present disclosure is not limited thereto, variations and improvements of the disclosed embodiments and other embodiments may be made based on what is described or illustrated in this document.

What is claimed is:

1. An image sensing device, comprising:
single-photon avalanche diodes (SPADs) disposed adjacent to each other; and
a connection region located between two adjacent SPADs among the SPADs,
wherein each of the SPADs includes:
an output node configured to output a voltage pulse; and
a biasing node disposed to overlap the output node and configured to receive a bias voltage,
wherein the connection region connects the biasing nodes included in the SPADs.

2. The image sensing device of claim 1, wherein the output node is a cathode, and the biasing node is an anode.

3. The image sensing device of claim 1, wherein the output node is an anode, and the biasing node is a cathode.

4. The image sensing device of claim 1, further comprising:
a first separation structure located between the two adjacent SPADs; and
a second separation structure disposed external to the SPADs.

5. The image sensing device of claim 4, wherein the first separation structure overlaps the connection region.

6. The image sensing device of claim 4, wherein the second separation structure includes a protruding structure configured to extend toward the first separation structure, and
wherein the connection region is located between the first separation structure and the protruding structure.

7. The image sensing device of claim 1, wherein the biasing node has a circular shape.

8. The image sensing device of claim 1, wherein the biasing node has a rounded rectangular shape.

9. The image sensing device of claim 1, wherein an impurity doping type of the output node is different from an impurity doping type of the biasing node.

10. The image sensing device of claim 4, wherein the first separation structure and the second separation structure are included in a substrate, and
wherein a depth of the first separation structure configured to extend from a first surface of the substrate toward a second surface of the substrate opposite to the first surface of the substrate is smaller than a depth of the second separation structure.

11. The image sensing device of claim 4, wherein the first separation structure and the second separation structure are included in a substrate, and
wherein a depth of the first separation structure configured to extend from a first surface of the substrate toward a second surface of the substrate opposite to the first surface of the substrate is equal to a depth of the second separation structure.

12. The image sensing device of claim 1, wherein the bias voltage is either a first bias voltage outputting a voltage pulse from each of the SPADs or a second bias voltage outputting a voltage pulse from only a SPAD to which the bias voltage is provided.

13. An image sensing device comprising:
a substrate having a first surface on which light is incident;
single-photon avalanche diodes (SPADs) located inside the substrate to be adjacent to each other;
a connection region configured to connect two adjacent ones of the SPADs;
a first separation structure located between the two adjacent ones of the SPADs; and
a second separation structure located external to the SPADs,
wherein the first separation structure extends toward the connection region from the first surface of the substrate.

14. The image sensing device of claim 13, wherein each of the SPADs includes:
an output node in contact with a second surface of the substrate that is opposite to the first surface of the substrate; and
a biasing node configured to overlap the output node and located inside the substrate.

15. The image sensing device of claim 14, wherein a doping type of the output node is different from a doping type of the biasing node.

16. The image sensing device of claim 13, wherein the second separation structure extends from the first surface of the substrate to a second surface of the substrate that is opposite to the first surface of the substrate.

17. The image sensing device of claim 13, wherein the connection region has a smaller width than the SPADs.

18. The image sensing device of claim 13, wherein the connection region has a smaller thickness than the SPADs.
